(19) United States
(12) Patent Application Publication
(10) Pub. No.: US 2019/0079618 A1
(43) Pub. Date: Mar. 14, 2019

(54) TOUCH PANEL DEVICE

(71) Applicant: Panasponic Intellectual Property Management Co., Ltd., Osaka (JP)

(72) Inventor: TAKAYOSHI MORIYASU, Kanagawa (JP)

(21) Appl. No.: 16/083,038

(22) PCT Filed: Mar. 14, 2017
(86) PCT No.: PCT/JP2017/010124

§ 371 Date: Sep. 7, 2018

(30) Foreign Application Priority Data
Mar. 23, 2016 (JP) 2016-058905

(51) Int. Cl. G06F 3/041; G06F 3/02; H03K 17/96; G06F 1/16

(52) U.S. Cl. CPC G06F 3/0412; G06F 1/1643; H03K 17/96; G06F 3/02

(57) ABSTRACT

A securing member is disposed so as to face an operation face of a touch panel, and a cover panel is disposed on a back side of a face of the securing member that faces the touch panel. The cover panel is provided with a cover-panel through-hole, and the securing member is provided with a securing-member through-hole that is wider than the cover-panel through-hole. A push button unit is disposed in the cover-panel through-hole. Each of the cover-panel through-hole and the push button unit has a tapered shape narrowing in a direction from the touch panel toward the cover panel.

### TECHNICAL FIELD

The present disclosure relates to a touch panel device provided in vehicle on-board equipment.

### BACKGROUND ART

Small-sized electronic devices, such as mobile telephone devices, are limited in size so as not to reduce their portability. To achieve flexible input operations under such a circumstance, a touch panel is used, in which key top indications are changeable. However, the touch panel does not produce a click feel such as obtained with physical push buttons. In an attempt to solve the problem, a key top is provided on a face of the panel (for example, see Patent Literature 1).

### CITATION LIST

### Patent Literature

PTL 1: Japanese Patent Unexamined Publication No. 2010-176552

### SUMMARY

The present disclosure provides a touch panel device that does not degrade its aesthetic quality while maintaining operability.

A touch panel device in accordance with an aspect of the present disclosure includes a touch panel, a cover panel, and a push button unit. The cover panel includes a first face opposed to an operation face of the touch panel, and a second face on a back side of the cover panel to the first face. The cover panel is also provided with a through-hole penetrating from the first face to the second face. The push button unit is disposed in the through-hole of the cover panel. Each of the through-hole and the push button unit has a tapered shape narrowing in a direction from the touch panel toward the cover panel.

### BRIEF DESCRIPTION OF DRAWINGS

FIG. 1 is an external appearance view illustrating a vehicle cabin in which vehicle on-board equipment according to a first exemplary embodiment of the present disclosure is mounted.

FIG. 2 is a block diagram illustrating a configuration of the vehicle on-board equipment of FIG. 1.

FIG. 3 is a perspective view illustrating an external appearance of the vehicle on-board equipment of FIG. 1.

FIG. 4 is an exploded perspective view illustrating a configuration of a touch panel device shown in FIG. 3.

FIG. 5 is a front view illustrating the configuration of the touch panel device of FIG. 4.

FIG. 6A is a cross-sectional view illustrating the configuration of the touch panel device of FIG. 5.

FIG. 6B is a cross-sectional view illustrating the configuration of the touch panel device of FIG. 5, in which a push-down section is pressed down.

FIG. 7 is a cross-sectional view illustrating an air layer area in the touch panel device of FIG. 6A.

FIG. 8 is a partial cross-sectional view illustrating a configuration of a touch panel device according to a second exemplary embodiment of the present disclosure.

FIG. 9 is a cross-sectional view illustrating a configuration of a touch panel device according to a third exemplary embodiment of the present disclosure.

### DESCRIPTION OF EMBODIMENTS

Vehicle on-board equipment employs a capacitive touch panel in order to allow input operations corresponding to various types of indications and to achieve advanced flat design. However, as mentioned earlier, the capacitive touch panel has a flat operation face, and it does not produce a click feel such as obtained with physical push buttons. Consequently, it is difficult for the user to perform operations without greatly moving the line of sight, and operational errors, such as unintentional operations and unintentional double tapping, are likely to occur. However, if key tops are provided on the touch panel, the flat design achieved by the touch panel is ruined, and the aesthetic quality is greatly degraded. In the following, a configuration that solves these problems and does not reduce aesthetic quality will be described.

### First Exemplary Embodiment

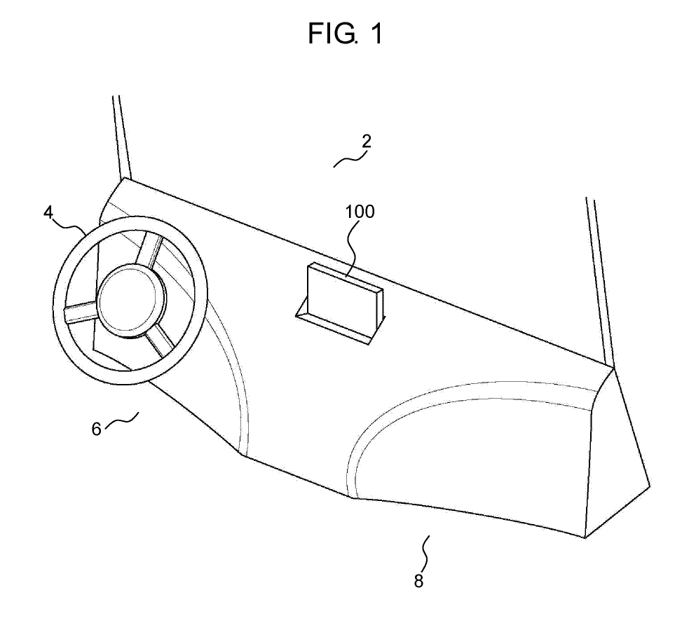

FIG. 1 is an external appearance view illustrating a vehicle cabin in which vehicle on-board equipment 100 is mounted, as viewed from the rear. In the front area of the vehicle cabin, driver seat 6 is disposed on the left, and front passenger seat 8 is disposed on the right. Steering wheel 4 is disposed in front of driver seat 6. Note that although steering wheel 4 and driver seat 6 are disposed on the left in FIG. 1, these may be disposed on the right. In addition, windshield 2 is disposed in front of steering wheel 4. Vehicle on-board equipment 100 is installed in a center console, which is on a side of, for example, to the right of, steering wheel 4. Vehicle on-board equipment 100 displays car navigation system images, for example.

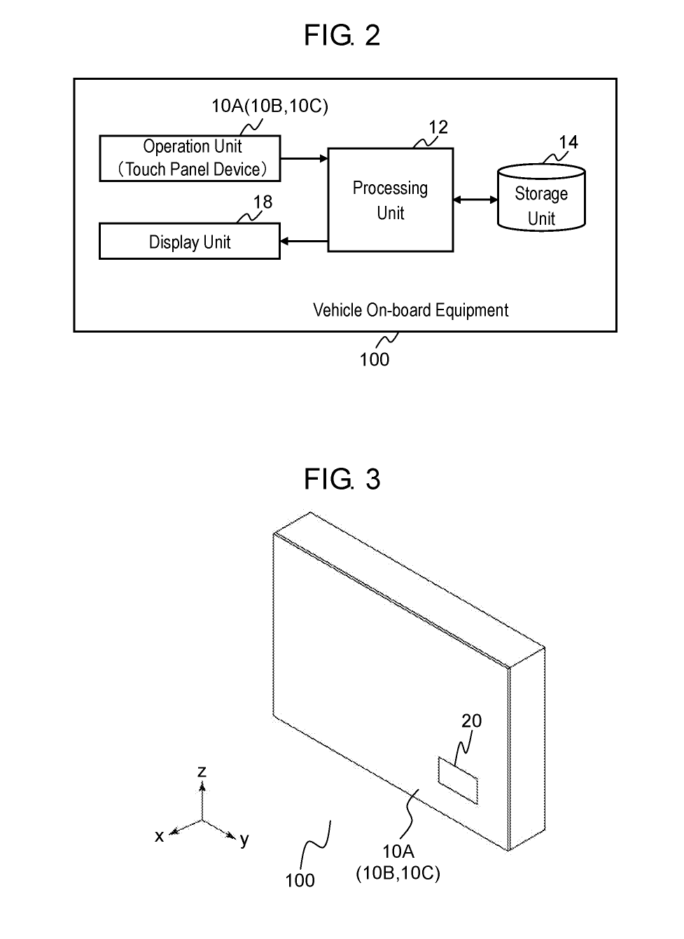

FIG. 2 is a block diagram illustrating the configuration of vehicle on-board equipment 100. Vehicle on-board equipment 100 includes touch panel device 10A, display unit 18, processing unit 12, and memory storage unit 14. Memory storage unit 14 is storage medium, such as a hard disk, that stores digital data, such as map data and music data. Processing unit 12 executes predetermined processes in vehicle on-board equipment 100. For example, processing unit 12 executes a navigation process with the use of the map data stored in memory storage unit 14. Processing unit 12 also executes a music playback process with the use of the music data stored in memory storage unit 14. These processes may be implemented by any known technique, and therefore will not be described herein. The predetermined process executed in processing unit 12 may be other than these processes. Processing unit 12 may be implemented by a general-purpose microcomputer and programs for controlling the microcomputer, or may be implemented by dedicated circuits.

Touch panel device 10A is a user interface. Touch panel device 10A receives an instruction from the user through a touch operation by the user, and outputs the received instruction to processing unit 12. Display unit 18 receives image data from processing unit 12 and displays the received data. Note that the instruction that is output from touch panel device 10A to processing unit 12 is used for a predetermined process in processing unit 12, and the image data that are output from processing unit 12 to display unit 18 are generated by another predetermined process in processing unit 12. The configuration of touch panel device 10A will be described later.

FIG. 3 is a perspective view illustrating the external appearance of vehicle on-board equipment 100. The x-axis, the y-axis, and the z-axis show a rectangular coordinate system. The y-axis and the z-axis are orthogonal to each other within a plane of touch panel device 10A included in vehicle on-board equipment 100. The x-axis is perpendicular to the y-axis and the z-axis, and extends in the thickness direction of vehicle on-board equipment 100. The respective positive directions of the x-axis, the y-axis, and the z-axis are defined by the directions indicated by the arrows in FIG. 3, and the negative directions thereof are defined by the directions opposite to those indicated by the arrows. Herein, the positive direction along the x-axis is a direction toward driver seat 6 and front passenger seat 8 shown in FIG. 1, which may also be referred to as “front face side” or “operation face side”. The negative direction along the x-axis is a direction toward windshield 2 shown in FIG. 1, which may also be referred to as “rear face side”. The positive direction along the z-axis may also be referred to as “upper face side”, and the negative direction along the z-axis may also be referred to as “lower face side”.

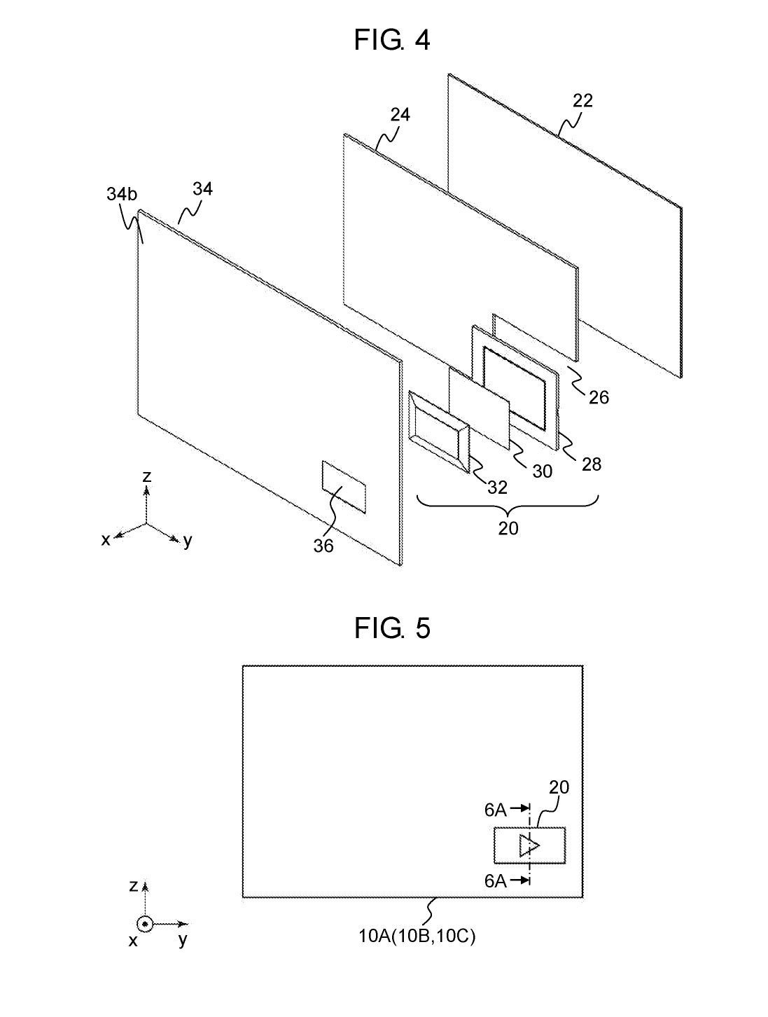

Vehicle on-board equipment 100 includes touch panel device 10A, as mentioned above, and touch panel device 10A includes push button unit 20. Push button unit 20 is a physical push button, which is pressed down by the user. Although only one push button unit 20 is provided herein, it is possible to provide a plurality of push button units. The shape of push button unit 20 as viewed in plan is not limited to a quadrangular shape, but may be freely selected from various shapes, including circular shapes and polygonal shapes, such as triangular shapes. Because touch panel device 10A includes later-described touch panel 22 as shown in FIG. 4, touch panel device 10A is also able to accept a touch operation by the user even in a region in which push button unit 20 is not disposed.

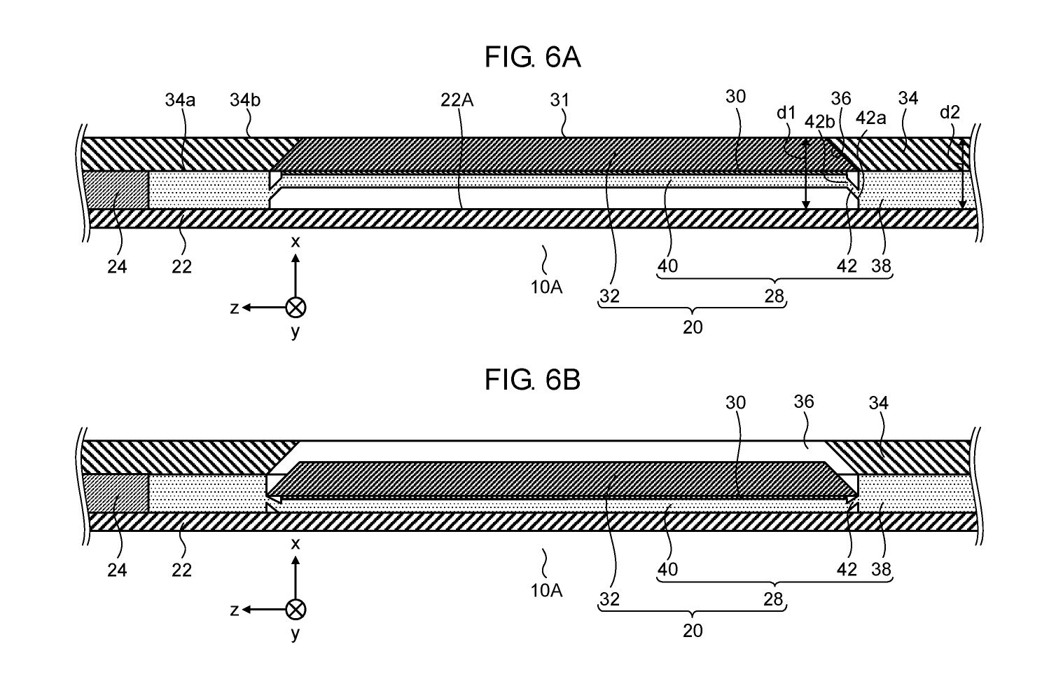

FIG. 4 is an exploded perspective view illustrating the configuration of touch panel device 10A. FIG. 5 is a front view illustrating the configuration of touch panel device 10A. FIGS. 6A and 6B are cross-sectional views illustrating the configuration of touch panel device 10A. FIG. 6A is a cross-sectional view taken along line 6A-6A in FIG. 5. Touch panel device 10A includes push button unit 20, touch panel 22, securing member 24, and cover panel 34. Securing member 24 is provided with securing-member through-hole 26 (hereinafter through-hole 26). Push button unit 20 includes switch section 28, securing layer 30, and push-down section 32. Cover panel 34 is provided with cover panel through-hole 36 (hereinafter through-hole 36). Furthermore, switch section 28 includes base part 38, switch face part 40, and flexural part 42.

Touch panel 22 is a capacitive touch panel that has a rectangular shape in the y-z plane. Any known technique may be used for the capacitive touch panel, and therefore the detailed description thereof will not be given herein. Hereinafter, the face of touch panel 22 on the operation face side is referred to as “operation face 22A of touch panel 22”. In FIG. 6A, operation face 22A is the upper face of touch panel 22. Securing member 24 is an optically transparent double adhesive tape or an optically transparent resin that has a rectangular shape, similar to touch panel 22. Securing member 24 secures later-described cover panel 34 to the operation face of touch panel 22. Therefore, securing member 24 is sandwiched between touch panel 22 and cover panel 34. Securing member 24 is provided with through-hole 26 penetrating therethrough along the x-axis. The shape of through-hole 26 as viewed in plan may be, but is not limited to, a quadrangular shape, similar to that of push button unit 20, and may be freely selected from various shapes, including a circular shape and polygonal shapes, such as a triangular shape. Although FIG. 4 shows that through-hole 26 is disposed in a region near a corner of securing member 24, the position at which through-hole 26 is to be disposed is not limited thereto.

Cover panel 34 has a rectangular shape, like touch panel 22 and securing member 24. For simplicity in illustration, cover panel 34 is depicted in FIGS. 3 and 4 with substantially the same outer dimensions as those of touch panel 22 and securing member 24. However, cover panel 34 may be freely designed in both size and shape because cover panel 34 is a decorative trim part. Generally, cover panel 34 is larger than touch panel 22 because a screen outer frame or the like is disposed around touch panel 22. The shape of cover panel 34 is not limited to a rectangular shape, either. Cover panel 34 is adhesive-bonded to securing member 24 on a face that faces the cover panel 34, so cover panel 34 is disposed more closer toward the operation face than touch panel 22. Hereinafter, a face of cover panel 34 that faces operation face 22A of touch panel 22 is referred to as first face 34a, and a face on the back side of touch panel 22 from first face 34a is referred to as second face 34b.

In addition, cover panel 34 is provided with through-hole 36 penetrating therethrough along the x-axis. Although only one through-hole 36 is provided herein, the number of through-holes 36 is not limited thereto, and a plurality of through-holes 36 may be provided. The shape of through-hole 36 as viewed in plan is not limited to a quadrangular shape, but may be freely selected from various shapes, including a circular shape and polygonal shapes, such as a triangular shape. Through-hole 36 is disposed so as to overlap through-hole 26.

Both through-hole 26 and through-hole 36 have a rectangular shape in the y-z plane. In addition, the cross section of through-hole 26 is wider than the cross section of through-hole 36, and through-hole 36 is disposed at a central portion of through-hole 26.

Push button unit 20 is disposed in a through-hole that is formed by through-hole 36 and through-hole 26 that communicate with each other. FIG. 5 shows an indication displayed by touch panel device 10A when vehicle on-board equipment 100 is performing a music playback process. Push button unit 20 has a rectangular shape. Push button unit 20 allows a symbol indicating an operation in the music playback process to be displayed in a region of display unit 18 shown in FIG. 2. The region is directly below push button unit 20. For example, push button unit 20 displays a symbol indicating a “playback” operation. When the user presses down push button unit 20, touch panel 22 accepts an instruction for playback, and processing unit 12 mentioned earlier causes music data to be played back.

Switch section 28 includes switch face part 40, flexural part 42, and base part 38. As seen from FIG. 6A, base part 38 has a ring shape. The outer shape of base part 38 is smaller than through-hole 26 shown in FIG. 4, and larger than through-hole 36 also shown in FIG. 4. The thickness of base part 38 along the x-axis is substantially the same as the thickness of securing member 24 along the x-axis. Thus, base part 38 is disposed within through-hole 26 between cover panel 34 and touch panel 22.

The inner diameter of base part 38 is substantially the same as the diameter of the face of push-down section 32 that faces securing layer 30. Flexural part 42 protrudes from the inner edge portion of base part 38 toward an inner area of through-hole 36. Flexural part 42 includes first edge portion 42a connected to an inner edge portion of base part 38 and second edge portion 42b on the reverse side thereof from first edge portion 42a. Switch face part 40, which constitutes the push-down face of switch section 28, is connected to second edge portion 42b. Switch face part 40 has a rectangular shape in the y-z plane. Securing layer 30 is disposed between switch face part 40 and push-down section 32. Push-down section 32 includes push-down operation face 31 on a back side thereof from a face that faces switch face part 40. Securing layer 30 is made of the same material as that of securing member 24. Securing layer 30 adhesive-bonds switch face part 40 and push-down section 32 together. Push-down section 32 and securing layer 30 are formed in a rectangular shape having substantially the same size as switch face part 40 in the y-z plane. The shape of each of switch face part 40, securing layer 30, and push-down section 32 as viewed in plan is not limited to a quadrangular shape, but may be freely selected from various shapes, including circular shapes and polygonal shapes, such as triangular shapes.

Thus, push-down section 32 is secured to switch face part 40 of switch section 28 at the face thereof on the back side from push-down operation face 31. Push-down operation face 31, which is the operation face of push-down section 32, is flush with second face 34b of cover panel 34. In other words, distance d1 between an outer edge portion of push-down operation face 31 and operation face 22A of touch panel are in agreement with distance d2 between second face 34b of cover panel 34 and operation face 22A of touch panel within a tolerance range. Thus, by providing continuity between cover panel 34 and push-down section 32, unity between cover panel 34 and push-down section 32, i.e., flat design, is obtained.

With such a configuration, when the user presses down push-down section 32 in the negative direction along the x-axis, touch panel device 10A deforms into a shape as shown in FIG. 6B. FIG. 6B is a cross-sectional view illustrating the configuration when push-down section 32 is pressed down. When a pressing force in the negative direction along the x-axis acts on push-down section 32, flexural part 42 deforms, causing switch face part 40 to move in the negative direction along the x-axis. This movement provides the user with a click feel. When this pressing force is removed, switch face part 40 moves back to the original position, and touch panel device 10A returns to the state shown in FIG. 6A.

Push button unit 20, particularly a side face portion of push-down section 32, has a tapered shape narrowing in a direction from touch panel 22 toward cover panel 34, in other words, in the positive direction along the x-axis. Cover-panel through-hole 36 also has a tapered shape corresponding to the side face portion of push-down section 32.

In FIG. 6A, push-down section 32 and cover panel 34 are disposed in a same layer, and switch section 28 and securing member 24 are disposed in another same layer. Here, the members within the same layer may be formed of the same type of material. Thereby, hue, refractive index, transmissivity and/or reflectivity, which relate to appearance, are unified, so uniformity in appearance is improved between cover panel 34 and push button unit 20. As a result, push button unit 20 appears as if it is not provided. Herein, any one of hue, refractive index, transmissivity, and reflectivity should preferably be made uniform as long as push button unit 20 appears as if it is not provided. Push-down section 32 and cover panel 34 are formed of the same type of material, such as polycarbonate, glass, and acrylic material. Switch section 28 and securing member 24 are also formed of the same type of material. For example, switch section 28 may be formed of silicone rubber, and securing member 24 may be formed of silicone-based tape.

Push-down section 32 is formed of a material having a higher hardness than switch section 28. Switch section 28 needs to deform when the user presses it down. For that reason, a relatively soft material is suitable for switch section 28. In contrast, push-down section 32, together with cover panel 34, needs to serve the purpose of protecting display unit 18 and touch panel 22. For that reason, a harder material than that of switch section 28 is suitable for push-down section 32. In touch panel device 10A, push-down section 32 and cover panel 34, which require hardness, are disposed in one layer, while switch section 28 and securing member 24, which require softness, are disposed in another layer. As a result, both requirements, meeting various levels of hardness required among various parts and achieving high aesthetic quality, can be satisfied.

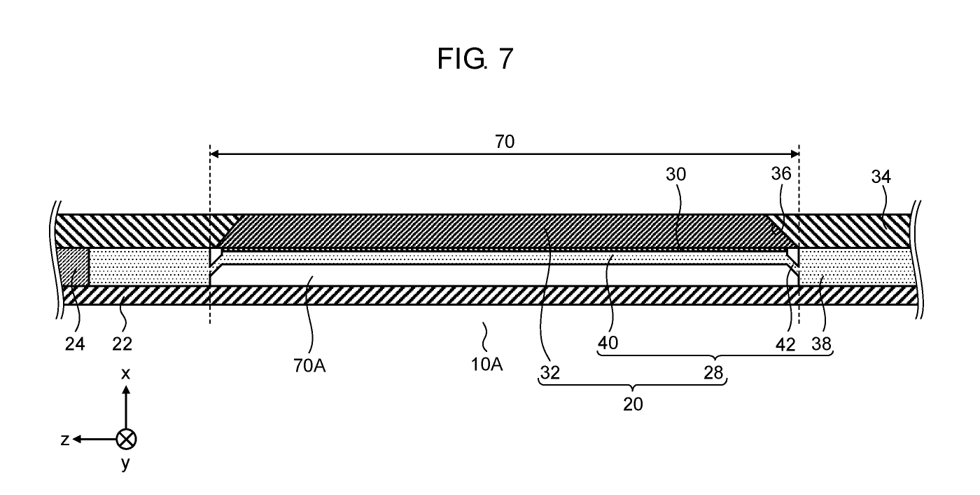

FIG. 7 is a cross-sectional view illustrating air layer area 70 in touch panel device 10A of FIG. 6A. Herein, the transmissivity of push-down section 32 is lower than the transmissivity of cover panel 34. For example, push-down section 32 has a smoked color. Herein, air layer 70A is formed between switch face part 40 and touch panel 22. Thus, air layer 70A causes the reflectivity of air layer area 70 to be higher than the reflectivity of the remaining area. In other words, the brightness of air layer area 70, which is covered by switch face part 40 and flexural part 42, is higher than the brightness of the remaining area. Such a difference in reflectivity makes the boundary between push-down section 32 and cover panel 34 conspicuous when the screen of touch panel 22 is turned off. However, setting the transmissivity of push-down section 32 to be lower than the transmissivity of cover panel 34 reduces the difference between the reflectivity of air layer area 70 and the reflectivity of the remaining area.

Meanwhile, setting the transmissivity of push-down section 32 to be lower than the transmissivity of cover panel 34 causes the portion of touch panel device 10A at push button unit 20 shown in FIG. 5 to be darker than the remaining portion thereof when the screen of touch panel 22 is turned on, consequently producing brightness unevenness. In order to deal with the problem, in touch panel 22 shown in FIG. 7, the brightness of the portion on which push-down section 32 is disposed, i.e., the brightness of air layer area 70, is set to be higher than the brightness of the portion on which cover panel 34 is disposed. That is, the brightness of air layer area 70 is partially made higher by local dimming

In the present exemplary embodiment, push button unit 20 is disposed within through-hole 36 of cover panel 34, which is disposed so as to face operation face 22A of touch panel 22. This reduces a portion of push button unit 20 that projects from cover panel 34. Moreover, operability is maintained because push button unit 20 is provided. Furthermore, because the portion of push button unit 20 that projects from cover panel 34 is small, the aesthetic quality is not degraded while the operability is maintained. What is more, because push-down section 32 and through-hole 36 face each other with a tapered shape, stickiness is reduced when push-down section 32 is pressed down. In addition, the gap between push-down section 32 and through-hole 36 is inconspicuous because push-down section 32 and through-hole 36 face each other with a tapered shape.

Also, push button unit 20 is made up of switch section 28, securing member 24, and push-down section 32, thus, it is possible to select a material that is suitable for each of the functions of the respective parts. In addition, because it is possible to select a material suitable for each of the functions of the respective parts, operability is improved. Push-down operation face 31 of push-down section 32 is flush with second face 34b of cover panel 34. This makes it possible to achieve flat design, preventing the aesthetic quality from degrading.

By setting the transmissivity of push-down section 32 to be lower than the transmissivity of cover panel 34, the difference in reflectivity between air layer area 70 and the remaining area is made smaller even when air layer 70A is formed. Since the difference in reflectivity is small, the boundary between push-down section 32 and cover panel 34 is inconspicuous when the screen is turned off. Moreover, the brightness of air layer area 70 is higher than the brightness of the remaining area. As a result, brightness unevenness is suppressed even though the transmissivity of push-down section 32 is lower than the transmissivity of cover panel 34. In addition, due to flat design, an uncomfortable feel is reduced when a map or a video image is displayed in a full screen including push button unit 20. Furthermore, when push button unit 20 is not used as a physical push button, push-down operation face 31 of push button unit 20 may be used as an operation face of a normal touch panel, along with the operation face of the cover panel 34. Despite its flat design, push button unit 20 provides the user with a click feel, preventing errors in operation.

In the present exemplary embodiment, cover panel 34 is disposed above operation face 22A of capacitive touch panel 22, but cover panel 34 is provided with through-hole 36 extending to touch panel 22. Push button unit 20 is disposed within through-hole 36, and the face of push button unit 20 and the face of cover panel 34 are made flush with each other. Moreover, push button unit 20 and cover panel 34 are fitted to each other in a tapered shape. Push button unit 20 improves operability, and also, push button unit 20 and cover panel 34 maintain flat design.

### Second Exemplary Embodiment

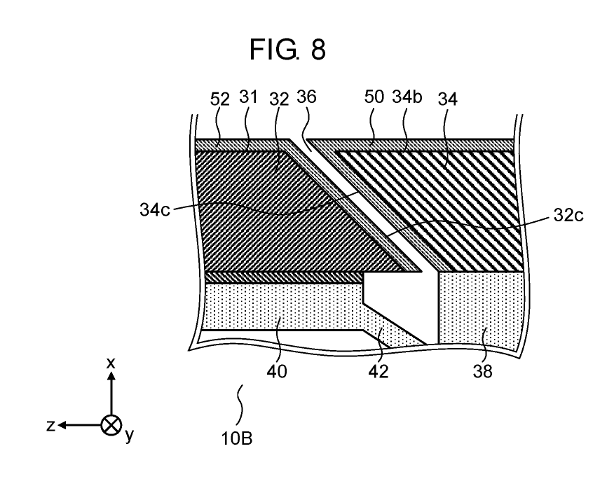

FIG. 8 is a partial cross-sectional view illustrating the configuration of touch panel device 10B according to a second exemplary embodiment of the present disclosure. FIG. 8 shows a portion between push-down section 32 and cover panel 34 in FIG. 6A. Touch panel device 10B is configured in a similar manner to the first exemplary embodiment, but it aims at making the parting line (gap) between push-down section 32 and cover panel 34 more inconspicuous. For that purpose, in the present exemplary embodiment, faces and edge faces of push-down section 32 and cover panel 34 are treated with an anti-glare treatment. Vehicle on-board equipment 100 according to the present exemplary embodiment has the same configuration as that illustrated in FIGS. 1 to 3. Touch panel device 10B has the same configuration as that illustrated in FIGS. 4 to 7, except for the anti-glare treatment. The description focuses on differences from the first exemplary embodiment.

As illustrated in FIG. 8, first anti-glare surface 50 is disposed on second face 34b and edge face 34c, which faces push-down section 32, of cover panel 34. First anti-glare surface 50 is treated with an anti-glare treatment. The anti-glare treatment may be implemented by any known technique, and therefore will not be detailed herein. It is possible to carry out the anti-glare treatment by processing or coating. In addition, second anti-glare surface 52 is disposed on push-down operation face 31 and edge face 32c, which faces cover panel 34, of push-down section 32. Second anti-glare surface 52 may be formed in a similar manner to first anti-glare surface 50.

In the present exemplary embodiment, the face of push-down section 32 and the operation face of cover panel 34 are treated with an anti-glare treatment, so that reflected light can be diffused. Moreover, because the reflected light is diffused, the boundary between push button unit 20 and cover panel 34 is made inconspicuous, and unity between push button unit 20 and cover panel 34 is achieved.

### Third Exemplary Embodiment

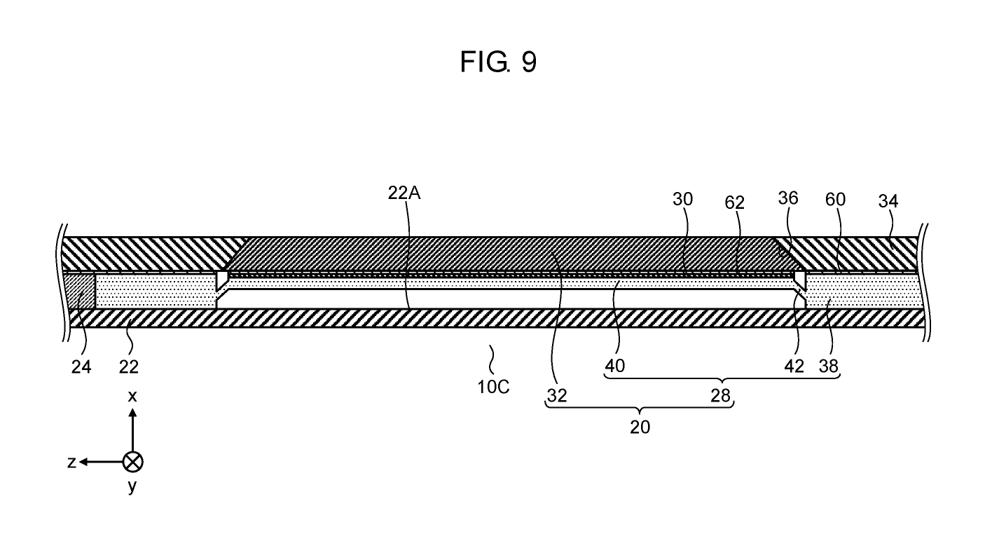

FIG. 9 is a cross-sectional view illustrating the configuration of touch panel device 10C according to a third exemplary embodiment of the present disclosure. FIG. 9 corresponds to FIG. 6A. Similar to the second exemplary embodiment, touch panel device 10C aims at making the parting line (gap) between push-down section 32 and cover panel 34 more inconspicuous. For that purpose, in the present exemplary embodiment, first circular polarizer plate 60 is disposed between cover panel 34 and touch panel 22, and second circular polarizer plate 62 is disposed between push-down section 32 and switch face part 40. Vehicle on-board equipment 100 according to the present exemplary embodiment has the same configuration as that illustrated in FIGS. 1 to 3. The description focuses on differences from the first and second exemplary embodiments.

As discussed earlier, securing member 24 is disposed on operation face 22A of touch panel 22, but first circular polarizer plate 60 is disposed closer toward the operation face side than securing member 24. In addition, cover panel 34 is disposed closer toward the operation face side than first circular polarizer plate 60. That is, first circular polarizer plate 60 is disposed between cover panel 34 and touch panel 22. Noted that securing member 24 and first circular polarizer plate 60 may be reversed. First circular polarizer plate 60 circularly polarizes the natural light that enters from the face on which cover panel 34 is disposed. First circular polarizer plate 60 may be, for example, constructed by bonding a ¼ phase retardation film with a linear polarizer film.

Also, securing layer 30 is disposed between switch face part 40 and second circular polarizer plate 62. Further, push-down section 32 is disposed on the back side of second circular polarizer plate 62 from the face thereof facing securing layer 30. Thus, second circular polarizer plate 62 is disposed between push-down section 32 and switch face part 40. Note that securing layer 30 and second circular polarizer plate 62 may be reversed. Second circular polarizer plate 62 circularly polarizes the natural light that enters from the face on which push-down section 32 is disposed. Second circular polarizer plate 62 may be constructed in a similar manner to first circular polarizer plate 60.

In the present exemplary embodiment, first circular polarizer plate 60 is disposed between cover panel 34 and touch panel 22, and second circular polarizer plate 62 is disposed between push-down section 32 and switch face part 40. Therefore, reflection of light is reduced between touch panel 22 and cover panel 34 and between touch panel 22 and push button unit 20. Also, because reflection of light is reduced between touch panel 22 and cover panel 34 and between touch panel 22 and push button unit 20, the appearance of cover panel 34 and that of push button unit 20 is made uniform.

In the first to third exemplary embodiments, touch panel 22 is preferably set so as to have a sufficient operation sensitivity in a region directly below push-down section 32. In other words, the sensitivity of touch panel 22 in a portion corresponding to push-down section 32 should be set higher than the sensitivity of touch panel 22 in a portion corresponding to cover panel 34. In this way, it is possible to achieve a touch panel operation without causing uncomfortable feel between push button unit 20 and cover panel 34.

Hereinabove, the present disclosure has been described with reference to various exemplary embodiments. It should be understood that these exemplary embodiments are merely illustrative examples. A person skilled in the art will understand that various changes and modifications of elements and combinations of processes are possible herein, and such changes and modifications are also within the scope of the present disclosure.

### INDUSTRIAL APPLICABILITY

The present disclosure is applicable to a touch panel device provided in vehicle on-board equipment.

### REFERENCE MARKS IN THE DRAWINGS

2 windshield
4 steering wheel
6 driver seat
8 front passenger seat
10A, 10B, 10C touch panel device
12 processing unit
14 memory storage unit
18 display unit
20 push button unit
22 touch panel
22A operation face
24 securing member
26 securing-member through-hole (through-hole)
28 switch section
30 securing layer
31 push-down operation face
32 push-down section
32c edge face
34 cover panel
34c edge face
34a first face
34b second face
36 cover-panel through-hole (through-hole)
38 base part
40 switch face part
42 flexural part
42a first edge portion
42b second edge portion
50 first anti-glare face
52 second anti-glare face
60 first circular polarizer plate
62 second circular polarizer plate
70 air layer area
70A air layer
100 vehicle on-board equipment

1. A touch panel device comprising:
a touch panel including an operation face;
a cover panel including a first face facing the operation face of the touch panel and a second face on a back side of the cover panel from the first face, the cover panel provided with a through-hole penetrating from the first face to the second face;
a securing member fixing the cover panel to the touch panel and provided with a through-hole that is wider than the through-hole of the cover panel; and
a push button unit disposed in the through hole of the cover panel,
wherein each of the push button unit and the through-hole of the cover panel has a tapered shape narrowing in a direction from the touch panel toward the cover panel,
the push button unit includes a switch section and a push-down section;
the switch section includes:
a frame-shaped base part disposed within the through-hole of the securing member between the cover panel and the touch panel;
a flexural part including a first edge portion connected to an inner edge portion of the base part and a second edge portion on a reverse side of the flexural part from the first edge portion, the flexural part protruding toward the through-hole of the cover panel; and
a switch face part connected to the second edge portion of the flexural part; and
the push-down section includes a secured face fixed to the switch face part of the switch section, and a push-down operation face on a back side of the secured face, the push-down section having a tapered shape narrowing in a direction from the touch panel to the cover panel.

2. (canceled)

3. The touch panel device according to claim 1,
wherein the push-down operation face of the push-down section is flush with the second face of the cover panel.

4. The touch panel device according to claim 1,
wherein at least one of hue, refractive index, transmissivity, and reflectivity is equal between a material that forms the push-down section and a material that forms the cover panel.

5. The touch panel device according to claim 1,
wherein the push-down section has a transmissivity lower than a transmissivity of the cover panel.

6. The touch panel device according to claim 5,
wherein the touch panel shows a higher brightness in an area covered by the switch face part or the flexural part of the switch section than in a remaining area of the touch panel.

7. The touch panel device according to claim 1,
wherein the operation face of the push-down section, an edge face of the push-down section that faces the cover panel, the second face of the cover panel, and an edge face of the cover panel that faces the push-down section are treated with an anti-glare treatment.

8. The touch panel device according to claim 1, further comprising:
a first circular polarizer plate disposed between the cover panel and the touch panel; and
a second circular polarizer plate disposed between the push-down section and the switch face part.
